(19) United States
(12) Patent Application Publication
(10) Pub. No.: US 2022/0364268 A1
(43) Pub. Date: Nov. 17, 2022

(54) METHOD OF GENERATING A DETERMINISTIC COLOR CENTER IN A DIAMOND

(71) Applicant: QUANTUM TECHNOLOGIES UG (HAFTUNGSBESCHRÄNKT), Leipzig (DE)

(72) Inventors: Jan Berend Meijer, Bochum (DE); Sébastien Pezzagna, Leipzig (DE); Tobias Lühmann, Leipzig (DE); Ralf Wunderlich, Leipzig (DE)

(21) Appl. No.: 17/619,302

(22) PCT Filed: Jun. 26, 2020
(86) PCT No.: PCT/EP2020/068110

§ 371 Date: Dec. 15, 2021

(30) Foreign Application Priority Data
Jun. 27, 2019 (DE) 10 2019 117 423.6

(51) Int. Cl. C30B 31/22; C30B 29/04; C30B 33/02; C01B 32/28

(52) U.S. Cl. CPC C30B 31/22; C30B 29/04; C30B 33/02; C01B 32/28; C01P 2002/52; B82Y 10/00

(57) ABSTRACT

A method generates at least one deterministic F-center in a diamond layer. By implanting a dopant in the diamond layer and incorporating at least one foreign atom in the diamond layer by low-energy bombardment for the formation of the F-center in a second step, conversion rates of greater than 70% can be achieved. This is a significant increase in relation to undoped diamond, in which the conversion rates are only around 6%. Via doping with a donor, such as phosphorous, oxygen or sulphur, a good conversion into negatively charged F-centers can be achieved, which are used for Qubit applications.

### CROSS REFERENCE TO RELATED APPLICATIONS

The present patent application is a national stage of, and claims priority to, Patent Cooperation Treaty Application No. PCT/EP2020/068110, filed on Jun. 26, 2020, which application claims the priority of the German patent application DE 10 2019 117 423.6, filed on Jun. 27, 2019, the disclosures of which are incorporated in the present patent application by reference.

### TECHNICAL FIELD

The present disclosure relates to a method for generating at least one deterministic color center in a diamond layer.

### BACKGROUND

Diamonds possess many exceptional physical and chemical properties. The mechanical features such as very high hardness, thermal conductivity and reaction resistance have been known for centuries and are used in many applications.

The optical properties of diamond have been studied since the 1970s, but the advent of new methods for nano-structuring and manufacturing diamond by chemical vapor deposition (CVD) has recently opened up exciting new areas of research and application in nano-optics and nano-photonics.

Nowadays it is possible to produce synthetically diamond in a high isotopic purity with nuclear spin-free carbon atoms (¹²C) and with certain crystal defects.

In particular, control over the nature and concentration of impurity atoms opens up new possibilities for endowing diamond with application-specific optical and electronic attributes.

Quantum technology in particular benefits from the extraordinary properties of diamond. In this context, quantum technology encompasses three major areas: Quantum computing, quantum cryptography and quantum sensing.

The precise detection of physical quantities is the basis of all natural sciences and a necessary prerequisite as well as the driving force behind almost all further technical developments. Although classical sensor principles are currently being refined, miniaturized, and combined, it is foreseeable that this will not lead to a decisive increase in the key parameters achieved so far, such as sensitivity and specificity. Quantum phenomena such as coherence, superposition and entanglement, on the other hand, can be used to detect quantities such as pressure, temperature, position, time and motion or acceleration, position, gravitation or electric and magnetic fields with unprecedented accuracy. Quantum sensors make use of different quantum systems, each of which has specific strengths.

Such a quantum system can be realized with the help of certain defects in diamonds (called color centers). Such a color center is e.g., the nitrogen defect center in a diamond. Nitrogen defect centers (NV centers) are atomic systems consisting of a nitrogen atom and a carbon defect in diamond. They absorb light in the wavelength range from about 450 nm to 637 nm and emit red light. Since the luminosity of these NV centers depends on the strength of an external magnetic field and the centers are atomically small, they can be used to measure magnetic fields with high local resolution but also good sensitivity. The usual high-sensitivity magnetic field sensors, such as SQUID sensors, only work under extreme cooling, which makes them very costly and technologically complex to operate. NV centers can be an important alternative here, as they can be used at room temperature and retain their quantum properties—unlike SQUID sensors, for example. Quantum computing technology also represents a very promising market. Even if the usefulness for normal computer use at home is considered very low today, quantum computers could displace the classical computer in some special fields and provide significantly more computing power in these fields due to their nature.

In classical computers, information is broken down into sequences of bits. A bit can occur in two distinguishable states, which are generally designated as 0 and 1 or “on” and “off”. The same principle can be used for quantum mechanical systems. However, it should be noted that in a quantum system, two states are considered distinguishable if they differ in at least one quantum number. The main difference between classical and quantum mechanical information systems is that in the quantum mechanical case, the system does not necessarily have to be in one of the two states 0 and 1. Rather, it can be in a superposition, i.e. a linear combination of both states. In the context of the present disclosure, the unit of such quantum information and also the quantum information itself are referred to as “qubit”.

In contrast to the classic bits of today's computers, qubits can thus process much more information and therefore offer the potential for computers with unprecedented computing capacity. Especially the production of such qubits is currently a topic in science, in which a lot of research work is invested. Scientists are looking for the best way to manufacture qubits and connect them together to form computing units in accordance with quantum laws.

Particularly in the focus of the development of qubits and thus for the development of quantum computers is, as in the field of quantum sensing, the NV-center in diamonds. This solid-state-based quantum system has several advantages over alternative qubit systems. The experimental implementation is simpler compared to atoms and ions held in elaborate evacuated traps for isolation. The long electron spin coherence time sets the NV center apart from other solid-state systems such as semiconductor quantum dots and superconductors. This is due to the nearly nuclear spin-free matrix as well as the low coupling of electrons to photon states of the lattice caused by the high Debye temperature of diamond. Another advantage is that the negatively charged NV center (NV⁻) exhibits these spin properties even at room temperature, which makes the operation of quantum devices under normal conditions conceivable. Moreover, carbon (¹³C) nuclei with nuclear spin are not only a source of decoherence, but are also useful in low concentrations for quantum technology applications.

However, the targeted (deterministic) fabrication and precise positioning of individual near-surface color centers, such as NV centers, is challenging. Once manufactured, they can no longer be moved.

For example, it is known from U.S. Pat. No. 7,122,837 B2 to produce NV centers by introducing nitrogen simultaneously with diamond growth or by implanting nitrogen after diamond growth is completed. This process can also be used for other types of atoms, such as hydrogen, boron, phosphorus and carbon, to produce specific color centers. However, the conversion rates of implanted nitrogen to NV centers achieved here by this method are very low.

It is known from EP 3 098 335 B1 that the charge stability of NV centers in diamond can be adjusted to a very high level by doping with, for example, phosphorus, arsenic, sulfur or boron-hydrogen complexes. However, this does not solve the problem of very low conversion rates.

Color centers close to the surface, for example NV centers, can be produced by irradiation with “slow” low-energy ions, the so-called Shallow Implantation. In the case of low-energy ions, however, conversion rates of only a few percent result in comparison to irradiation with high kinetic energies, as is the case for the methods of U.S. Pat. No. 7,122,837 B2 and EP 3 098 335 B1. Thus, 20-50 ions are required to be implanted here to generate a near-surface NV center. This inefficiency leads to many defects within the diamond and disturbs the properties of the NV center.

### SUMMARY

It is therefore an objective of the present disclosure to provide a method for enabling high conversion rates of introduced ions into color centers. In particular, these conversion rates should be at least 50%.

This task is solved with the method according to an independent claim, a diamond layer according to another independent claim and a use according to another independent claim. Advantageous further examples are indicated in the subclaims and in the following description together with the figures.

It was recognized that this task can be solved in a surprising way by implanting a dopant in a diamond layer in a first step and incorporating an impurity atom to form the color center in a second step by means of ion bombardment, the ion bombardment with impurity atoms having an ionic fluence of up to 10¹⁰ cm⁻². Thus, very high conversion rates of more than 70% can be achieved. The high conversion rates result in an increased probability for the method according to the disclosure to successfully link or interconnect individual color centers, in particular NV centers, in order to thereby produce usable qubit registers or qubit sensors, each consisting of two or more qubits. In addition, near-surface layers with color centers can be produced in this way without the need for additional surface processing, for example surface ablation.

In the context of the present disclosure, a “diamond layer” can be a layer in a diamond bulk material as well as a defined diamond layer deposited on a substrate of the same or different material.

It is suspected that, for example, with respect to NV-centers, hydrogen that is normally highly mobile appears to accumulate on the surface of the diamond layer, where it forms an NVH complex that is not usable. Moreover, defects (vacancy—V) created by nitrogen-ion bombardment, even if low energy, are mobile and accumulate at the surface where they are no longer available for the formation of NV centers.

The dopant, in particular a donor, now appears to bond the hydrogen (donor—H), which also appears to create a donor.

As a result of this and the introduced donor or acceptor itself, a charging of the vacancy (V⁻ or V⁺) occurs, whereby the vacancy becomes immobile and no longer diffuses to the surface, but is available to form the color center. Due to the dopants, Frenkel defects (vacancy with interstitial atom V⁰—C_{I}) become negatively charged→V⁻—C. These dissociate at 500° C. to form V⁻ and C_{I}⁰. Therefore, more V⁻ are available for NV formation. In boron or intrinsic diamonds, the Frenkel defects are predominantly neutral and recombine (heal out).

The method according to the disclosure for generating at least one deterministic color center in a diamond layer is characterized in that, in a first step, at least one dopant is implanted in the diamond layer and, in a second step, at least one impurity is incorporated in the diamond layer by means of low-energy ion bombardment to form the color center, the ion bombardment being carried out with impurities having an ion fluence of up to 10¹⁰ cm⁻².

In an example, it is provided that a donor, preferably phosphorus, oxygen, sulfur or lithium, or an acceptor, preferably boron, is used as the dopant. Mixtures of multiple dopants, including mixtures of donors and acceptors, may also be used to make particular adjustments. Sulfur is most preferred of these, as it can be used to achieve the highest conversion rates of greater than or equal to 70%, particularly 75.3%. However, this is entirely unexpected and surprising because sulfur is considered to be a poor donor for diamond, since free charge carriers cannot be detected in Hall measurements. Most importantly, sulfur seems to ensure that hydrogen is bound, increasing the conversion rate. Phosphorus (approx. 60%) and oxygen (approx. 70%) are also excellent donors.

Also the publication Karin Groot-Berning et al.: “Passive charge state control of nitrogen-vacancy centers in diamond using phosphorous and boron doping”, Phys. Status Solidi A 211, No. 10, 2268-2273 (2014) already describes a two-step process with a doping and a subsequent impurity implantation with nitrogen. In this study, the aim was to stabilize the generated NV centers. Ion fluences of more than 10¹¹ cm⁻² were used for this purpose, and conversion rates of about 5% were determined. With the method according to the disclosure, however, considerably higher conversion rates can now be achieved, which is probably due to the fact that considerably fewer point defects or vacancies are generated as a result of the significantly reduced ion fluences of only up to 10¹⁰ cm⁻². Such point defects or vacancies would, however, lead to additional p-doping or trapping centers, which in turn compensates for n-doping by, for example, phosphorus or sulfur, or binds charge carriers, as a result of which no free negatively charged point defects can arise, which would prevent the conversion of N to NV.

In a further development, it is provided that the impurity is selected from the group of nitrogen, magnesium, carbon, lead, boron, noble gases, silicon, transition metals and tin. In boron doped diamond, divacancies (V—V) are increasingly formed at 800° C. (more strongly than in intrinsic diamond, in N-type diamond this is not observed or only very weakly). For the formation of e.g. SiV one needs (V—V), which thus leads in boron diamonds to an increase of the conversion rate of silicon impurities into SiV. Thus, promising color centers with a high conversion rate can be produced.

A preferred combination is sulfur as donor and nitrogen as impurity.

The fact that sulphur has such advantageous properties also seems to be possibly due to the fact that the energy level of sulphur matches fairly well that of a point defect (V) in diamond. This is thought to allow very good transfer (mott-hopping) of the electron from sulfur to the point defect.

Furthermore, when sulfur is used as a dopant, it appears to stabilize the diamond material, probably because sulfur retards the formation of graphite at high temperatures due to the mutually repelling defects. More specifically, sulfur seems to suppress the formation of complex defect clusters because the charged vacancies or point defects (V⁻) repel each other. Therefore, the temperatures at the second annealing step can then be chosen higher, which is beneficial for the conversion rate.

In a further example, it is provided that the color center is an NV⁻ center. This color center is particularly promising for quantum technology applications.

In a further example, it is provided that the dopant concentration is in the range 10¹⁷ cm⁻³ to 10¹⁹ cm⁻³, preferably between 1×10¹⁸ cm⁻³ and 9×10¹⁸ cm⁻³. As a result, the vacancies created during the implantation of impurity atoms are negatively charged, which leads to an increased probability of the formation of NV centers and a reduced probability of the formation of VV centers.

In a further example, it is provided that the depth of the implanted dopants is at least equal to the depth of the incorporated impurity atoms. Thus, the beneficial effects of the dopants are available for all incorporated impurity atoms, because these impurity atoms do not simply create defects, so that very high conversion rates can be achieved.

In a further development, it is provided that the dopant implantation is carried out by bombardment with the dopants, in particular with energies of less than or equal to 150 keV. This achieves very high conversion rates near the surface. Although other methods can also be used for the implementation of dopants, bombardment provides particularly good results because defined depths for the concentration distribution of the dopants can be set.

In a further development, it is provided that the dopant implantation is carried out in at least two successive different steps, because in this way a very homogeneous dopant distribution can be set over the depth of the diamond layer. For example, the dopant implantation is carried out by dopant bombardment at different fluences and/or energies.

In a further development, it is provided that the ion bombardment with impurity atoms is carried out with an ionic fluence in the range 10⁴ cm⁻² to 10¹⁰ cm, preferably in the range 10⁷ cm⁻² bis 10¹⁰ cm⁻², most preferably in the range 10⁸ cm⁻² bis 10¹⁰ cm ⁻², in particular in the range 10⁹ cm⁻² bis 10¹⁰ cm⁻². In this way, particularly high conversion rates can be achieved.

In a further example, it is provided that the depth of the color centers in the diamond layer is in the range 5 nm to 100 nm, preferably in the range 10 nm to 50 nm, in particular in the range 10 nm to 30 nm, and preferably between 20 nm and 30 nm. Thus, the color centers are located very close to the surface and can be easily used for quantum technology applications. More specifically, the color centers can be easily addressed without being disturbed by surface effects. It is true that, on the one hand, the production of color center is disturbed especially near the surface, because band bending occurs more here, which prevents the formation of the color centers. And on the other hand, unavoidable crystal disturbances at the surface facilitate the penetration of interfering impurity atoms such as hydrogen. However, for the fabrication of sensors or the addressing of qubits, color centers at the surface are inevitable. In the aforementioned depth range, it is now possible to generate undisturbed qubits that can nevertheless be addressed well.

In a further development, it is provided that after the dopant implantation a first tempering step takes place, wherein
i) the tempering temperature of the first tempering step is preferably in the range 800° C. to 2000° C., more preferably in the range 800° C. to 1400° C., in particular in the range 1000° C. to 1400° C., preferably not more than 1200° C. and most preferably in the range 1000° C. to 1200° C. and/or
ii) the time for the first tempering step is preferably between 1 h and 24 h, in particular between 2 h and 10 h, preferably between 3 h and 6 h. Through this first annealing step, the dopants are electrically activated, so that they can easily transfer their charge to the generated vacancies and color centers. In addition, a healing of dopant implantation-induced defects takes place and the dopants will arrange themselves on substitution sites, which is particularly advantageous for high conversion rates. This is particularly advantageous for dopant implantation in the context of a dopant bombardment.

The publication Karin Groot-Berning et al: “Passive charge state control of nitrogen vacancy centers in diamond using phosphorous and boron doping”, Phys. Status Solidi A 211, No. 10, 2 268-2273 (2014) describes an annealing step at 1500° C. for the doped diamond material. However, the inventors have now found that the conversion rate is particularly high when this annealing step is performed at no more than 1200° C. However, the physical background to this is still unknown.

In a further example, it is provided that after the dopant implantation and/or after the first annealing step, an oxygen plasma is used to clean the surface of any graphite that may be present.

In an advantageous further example, it is provided that a second annealing step is carried out after the impurity atom incorporation, wherein
iii) the tempering temperature of the second tempering step is preferably lower than that of the first tempering step and/or preferably in the range 600° C. to 1300° C., in particular in the range 800° C. to 1000° C. and/or
iv) the time for the second tempering step is preferably between 1 h and 24 h, in particular between 2 h and 10 h, preferably between 3 h and 6 h. The second tempering step allows very high conversion rates, these being particularly high when the temperature is lower than during the first annealing step. This second annealing step increases the mobility of vacancies and impurity atoms, thus increasing the probability of formation of the color centers. It also heals impurity atom implantation-induced defects that would ultimately also prevent or at least disrupt entanglement of the qubits.

In an advantageous further development, it is provided that the first tempering step and/or the second tempering step comprises heating and/or laser irradiation, in particular rapid thermal annealing. In this way, the annealing is particularly effective and very high conversion rates can be achieved.

In a further example, it is provided that a raising of the Fermi level is performed because it allows the charge of the defect to be adjusted. Preferably, the Fermi level increase is performed by LASER irradiation, electron bombardment or voltage application. Preferably, the Fermi level increase can occur during impurity implantation, after impurity implantation, and/or during the second annealing step. However, sulfur also appears to cause the Fermi level to be raised, thereby increasing the conversion rate.

In a further development, it is provided that the diamond layer is present in a diamond material which is at least of pure quality (“electronic grade”). Preferably, the hydrogen content in the diamond layer should be less than 10¹⁷ cm⁻³. This allows particularly high conversion rates to be achieved. Advantageously, sulphur is also used as a donor, because this appears to bind hydrogen, which further increases the conversion rate.

In a further development, it is provided that the diamond layer is formed as a layer, preferably as a surface layer, within a diamond material extending over a greater depth. Then the color center is particularly easy to produce. Alternatively, however, diamond layers can also be produced directly on substrates using known processes.

Independent protection is claimed for the diamond layer according to the disclosure with at least one deterministic color center, which is characterized in that the type of impurity used to form the color center is present in the diamond layer in a number of atoms which is at most twice as large as the number of the color center in the diamond layer. This corresponds to a conversion rate of at least 50%, because then one of every two impurity atoms introduced contributes to the formation of a color center. Preferably, the impurity atom used to form the color center is present in the diamond layer in a number of atoms which is at most 1.67 (this corresponds to a conversion rate of at least 60%) times as large, in particular at most 1.43 (this corresponds to a conversion rate of at least 70%) times as large, as the number of the color center in the diamond layer.

Furthermore, independent protection is claimed for the use of the diamond layer according to the disclosure or the diamond layer produced according to the disclosure as a qubit container, preferably in the context of a sensor and/or in the context of quantum cryptography and/or in the context of a quantum computer application. For example, a color center acting as a qubit in the diamond layer, in particular an NV⁻-center, could be used in an AFM tip for particularly accurate measurements.

As stated, although dopants are also used in EP 3 098 335 B1, they are only used to influence the optical properties of the pre-existing color center, namely to transform pre-existing NV⁰-centers into NV⁻-centers or to ensure the long-term stability of NV⁻-centers, whereas in the context of the present disclosure the dopant is used for deterministic formation of the color center itself. The sequence of implantation and the healing process according to the disclosure also have an advantageous effect in this respect. Whereas in EP 3 098 335 only one annealing step (tempering step) is carried out after the implantation of dopant and impurity atom for charge stability of the color center, in the process according to the disclosure a further annealing step (tempering step) is used between the implantation of dopant and impurity atom. Only in this way can the chemical potential be positively changed in a targeted manner and the behavior of the defects be controlled during the implantation of the atoms of the color center in the second process step according to the disclosure The mode of action of the dopants implanted in the process according to the disclosure is thus to be clearly distinguished from the process carried out in EP 3 098 335 B1.

The features and further advantages of the present disclosure will become clear below from the description of preferred examples in connection with the figures. Thereby, purely schematically:

### BRIEF DESCRIPTION OF THE DRAWINGS

FIG. 1 block diagram of the process according to the disclosure,

FIG. 2 illustration of the sample preparation,

FIG. 3 concentration distribution of the dopants,

FIG. 4 method for determining the background signal,

FIG. 5 method for determining the reference signal,

FIG. 6 obtained conversion rates for nitrogen,

FIG. 7 change in fluorescence as a function of the second tempering step and

FIG. 8 overview of the determined coherence times.

### DESCRIPTION

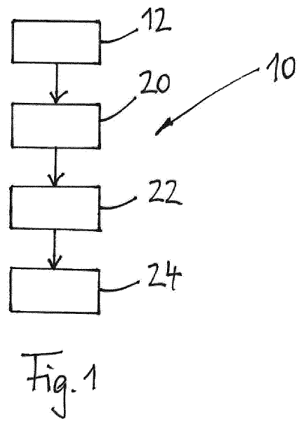

In FIG. 1 illustrates an example method 10 for producing a deterministic color center.

In a first step 12, a diamond 14 (type IIa, CVD-grown, “electronic grade”, impurities: [N]<5 ppb, [B]<1 ppb, (001)-face polished, lying upwards) dopants are implanted in a diamond layer 15 (corresponding to the depth extent of the doped region of the diamond or the depth extent of the subsequently generated color centers 54) of the diamond 14. This is done with an ion beam source 16, preferably using an aperture 18 to locally define the implantation.

The ion beam source 16 has a cesium sputter source acting on different cathodes, after which the sputtered ions are accelerated in an electric field.

This is followed by an initial annealing step 20 to heal any defects that may have occurred during implantation. Furthermore, this causes the dopants to arrange themselves on the substitution sites in the diamond lattice. Additionally, electrical activation of the dopants occurs so that they readily release their charge. For the first annealing step, a specific first annealing regime is used, which may provide for the application of a specific temperature for a specific time, or different subsequent temperatures applied for specific times in each case.

Preferably, an oxygen plasma may be used after the first annealing step 20 to clean the surface of any graphite that may be present.

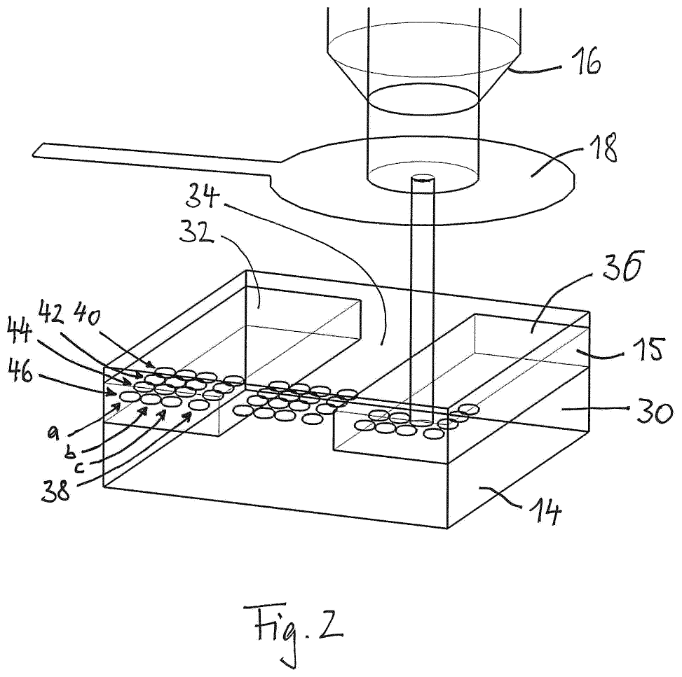

Subsequently, an ion bombardment 22 is carried out, again with the ion beam source 16, e.g. of the Kaufmann type, in order to incorporate the impurity atoms, whereby preferably the additional aperture 18 with an aperture opening of 50 μm is again used (cf. FIG. 2).

Finally, a second annealing step 24 is carried out to heal defects created during the incorporation of the impurity atoms or to guide the vacancy defects towards the impurity atoms by increasing their mobility in order to form color centers. For the second annealing step, a specific second annealing regime is used, which may also provide for the application of a specific temperature for a specific time, or different temperatures subsequently applied for specific times in each case.

Tempering 20, 24 may each be performed using a common tempering method, preferably selected from the group consisting of heating, for example using a hot plate, IR radiant heat and/or LASER irradiation, but other methods may also be used.

During at least one of steps 22, 24, additional increasing of the Fermi level may be performed, which is preferably performed by LASER irradiation, electron bombardment, or voltage application.

FIG. 2 shows how individual test samples 30 were prepared.

Spatially separated doping regions 32, 34, 36 are provided in each case, which are formed by different dopings by means of the first step 12. Individual doping regions can also remain undated for comparison purposes.

In the context of experimental sample 30, doping region 32 is a boron-doped region, doping region 34 is an undated (intrinsic region), and doping region 36 is a phosphorus-doped region. Other doping regions (not shown) were also used in which oxygen and sulfur were used as dopants.

In order to achieve the most homogeneous doping of 2×10¹⁷ cm⁻³ and 2×10¹⁸ cm⁻³, respectively, the implantation of boron/phosphorus was carried out in three steps each (three different energies and three different fluxes).

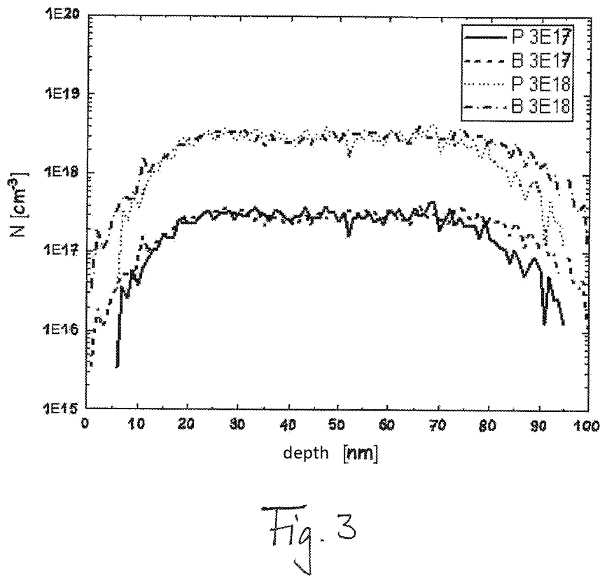

The concentration distributions of the dopants shown in FIG. 3 show a very constant plateau with the following fluxes over the depth, which lies between approx. 25 nm and approx. 75 nm with a center at around 50 nm (cf. Tables 1 and 2, simulated using SRIM):

TABLE 1
Boron

| | Fluence (cm⁻²) | Fluence (cm⁻²) |
|---|---|---|
| Energy (keV) | for 2 × 10¹⁷ cm⁻³ | for 2 × 10¹⁸ cm⁻³ |
| 12 | 5.6 × 10¹¹ | 5.6 × 10¹² |
| 25 | 6.4 × 10¹¹ | 6.4 × 10¹² |
| 40 | 1.1 × 10¹² | 1.1 × 10¹³ |

TABLE 2
Phosphorus

| | Fluence (cm⁻²) | Fluence (cm⁻²) |
|---|---|---|
| Energy (keV) | for 2 × 10¹⁷ cm⁻³ | for 2 × 10¹⁸ cm⁻³ |
| 30 | 3.4 × 10¹¹ | 3.4 × 10¹² |
| 50 | 5.1 × 10¹¹ | 5.1 × 10¹² |
| 90 | 1.3 × 10¹² | 1.3 × 10¹³ |

As part of the first tempering step 20, these generated test samples 30 were tempered, namely, for example, at 1200° C. or 1600° C. for 4 h.

In each of the doping region 32, 34, 36, graphite markers 38 were deposited on the samples for orientation. This was done by high dose implantation of carbon, resulting in graphitization of these regions.

In addition to the graphite markers 38, various impurity atom regions 40, 42, 44, 46 were then generated by ion bombardment 22. For example, the impurity atom regions 40 each involve carbon as an impurity atom, the impurity atom regions 42 each involve nitrogen as an impurity atom, the impurity atom regions 44 each involve tin as an impurity atom, and the impurity atom regions 46 each involve magnesium as an impurity atom, for example.

In each case, three different fluxes a, b, c were used, namely, for example, on the basis of test sample 30, a fluence of 10¹⁰ cm⁻² for the impurity atom regions 40a, 42a, 44a, 46a, a fluence of 10¹¹ cm⁻² for the impurity atom regions 40b, 42b, 44b, 46b and a fluence of 10¹² cm⁻² for the impurity atom regions 40c, 42, 44c, 46.

For carbon, nitrogen and magnesium, bombardment energies of 28 keV, 40 keV and 50 keV were used in order to generate a depth profile (diamond layer 15, average implantation depth 50 nm) that was as homogeneous as possible over the same depth range as the dopants. For tin, this was not possible due to its atomic mass combined with the limitation of the ion beam source to 100 keV, so that only 80 keV was used there (average implantation depth 25 nm). The cathode material used for the respective bombardment 22 was a carbon cathode for carbon impurity atoms, a ¹²C¹⁴N cathode for nitrogen impurity atoms, a ²⁴Mg¹H cathode for magnesium impurity atoms and a tin cathode for tin impurity atoms.

The implantation depths thus achieved corresponded to those of the dopant distribution (diamond layer 15). Furthermore, they were small enough to achieve only a low ion scattering of less than 10 nm, but at the same time large enough to exclude or minimize the described negative effects of the diamond surface.

The second tempering step 24 was then performed in each case, using different temperatures of 600° C., 800° C., 1000° C. and 1200° C. for this purpose.

Thereafter, the fluorescence intensities for each of the impurity atom regions 40, 42, 44, 46 with respect to all fluxes a, b, c were determined by a confocal fluorescence microscope, using graphite markers 38 for orientation and retrieval.

For this purpose, either air or oil objectives and two possible LASER excitations of 532 nm and 488 nm were used. LASER reflection was suppressed with a notch filter and different spectral filters were used to select the desired fluorescence bands: neutral vacancy V⁰ (GR1 center with ZPL at 741 nm), NV center (ZPL of NV⁰ at 575 nm, ZPL of NV⁻ at 638 nm), SnV center (ZPL at 620 nm) and MgV center (ZPL at 557 nm).

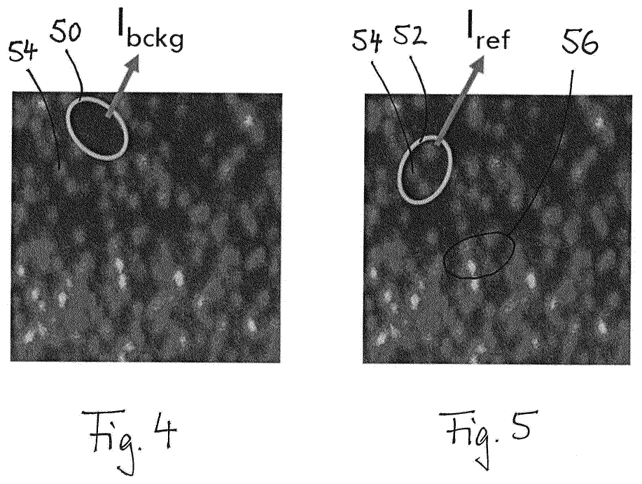

The background intensity (I_{backg}) was determined in a certain region 50 (cf FIG. 4) in which no color centers appeared, and the intensity of these color centers 54 (I_{ref}) was determined in a geometrically identical region 52 (cf. FIG. 5) in which a countable number of color centers 54 are located.

The sections shown in FIGS. 4 and 5 have edge lengths of about 10×10 μm². Color centers 54 usually appear distinguishable, i.e., countable, in such images when their number does not exceed 3 to 4 per μm².

If the color centers 54 were so countable, the conversion rate could be inferred directly by comparison with the ions that had flowed onto that area.

If this was not possible, the conversion rate was determined via reference values as follows. The reference value (I_{single}) per color center 54 is determined as follows:

I_{single}=(I_{ref}−I_{bckg})/(number of color centers 54 in region 52)

For any given region 56, the density D_{FZ} of the color centers 54 can now be determined from the total intensity Iₑₙₛ from the area S of that region 56 using the following relationship:

D_{FZ}=1/S*(Iₑₙₛ−I_{backg})/I_{single}

From this, the conversion rate UR can be determined by:

UR=D_{FZ}/(ionic fluence during impurity atom incorporation).

Finally, the spin coherence time T2 and T2* were determined.

It was found that the conversion rate for NV-centers 54 for intrinsic diamond is about 6%-8%.

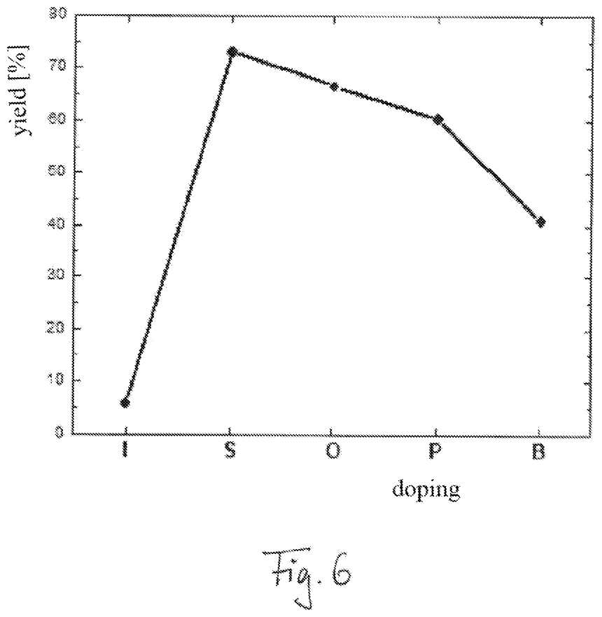

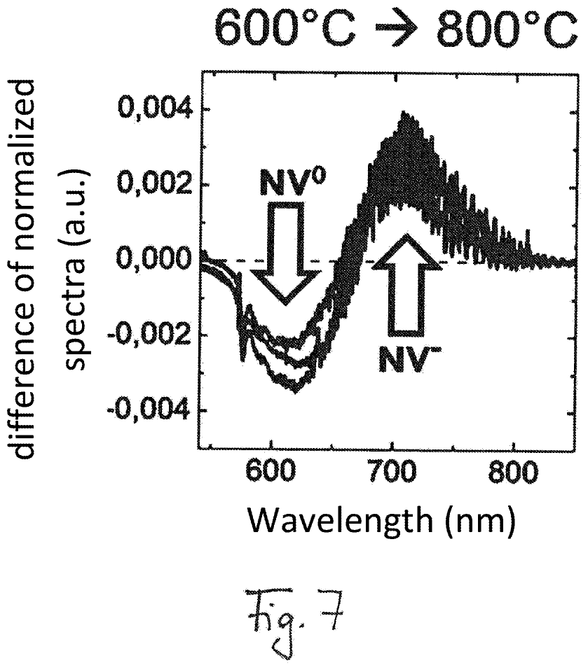

Doping with sulfur, oxygen, phosphorus or boron can significantly increase the conversion rate (sulfur: 75%, oxygen: 7%, phosphorus: 50% and boron:40%—see FIG. 6). However, only sulfur, oxygen and phosphorus can generate NV⁻-centers that enable qubits. These values were obtained with the following parameters: For doping, fluences and energies of phosphorus: 40 keV at 4.1×10¹² cm⁻² and 80 keV at 4.1×10¹² cm⁻², oxygen: 25 keV at 2.1×10¹² cm⁻² and 50 keV at 4.2×10¹² cm⁻², sulfur: 40 keV at 1.6×10¹² cm⁻² and 80 keV at 3.7×10¹² cm⁻² and boron: 25 keV at 2.1×10¹² cm⁻² and 50 keV at 4.2×10¹² cm⁻² were used, while impurity implantation with nitrogen was done at a maximum fluence of 10¹⁰ cm⁻² and an energy of 40 keV.

Although this was not to be expected, very high conversion rates can therefore be achieved, especially with sulphur.

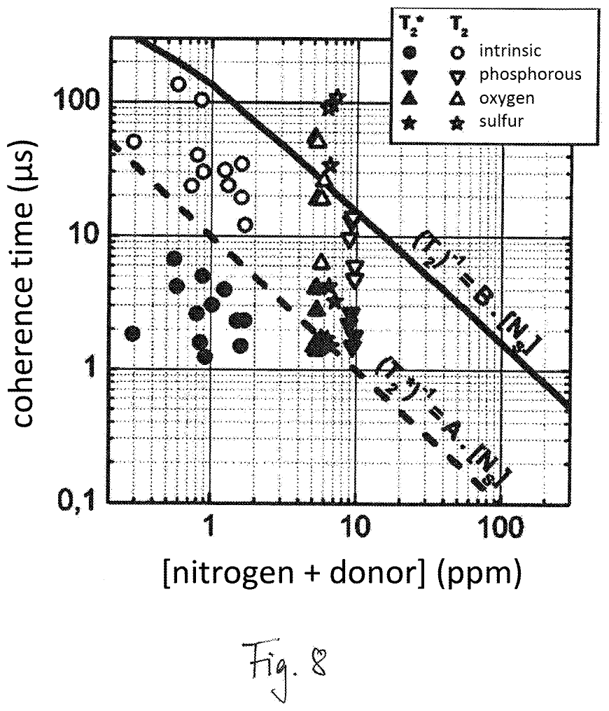

A higher temperature in the second annealing step 24 may result in a higher conversion rate to NV⁻ centers (cf. FIG. 7, where this is shown by the difference in normalized fluorescence spectra for phosphorus as a dopant and an annealing change from 600° C. to 800° C. for different samples), which can be explained by the fact that the higher temperature cures vacancies acting as acceptors and also causes a higher mobility of vacancies from the nitrogen.

FIG. 8 shows that the coherence times for sulfur doping are excellent, i.e., as high as if there were no doping at all but an intrinsic diamond. For oxygen the coherence times are still very good, while for phosphorus doping not so good coherence times can be achieved.

Similar results were obtained for magnesium and tin, so that overall, it can be stated that doping can significantly increase the conversion rates. In this context, doping with a donor, such as phosphorus, oxygen or sulfur, can achieve a very good conversion rate into negatively charged color centers, which can be used for qubit applications.

Due to the high conversion rates, this gives a possibility to generate color centers deterministically in diamond.

A Feature 1 of the disclosure is a method (10) for generating at least one deterministic color center (54) in a diamond layer (15), characterized in that:
in a first step (12), at least one dopant is implanted in the diamond layer (15), and
in a second step (22), at least one impurity is incorporated in the diamond layer (15) by means of low-energy ion bombardment to form the color center (54), the ion bombardment (22) with impurities having an ionic fluence of up to 10¹⁰ cm⁻².

A feature 2 of the disclosure is a method (10) according to feature 1, characterized,
in that a donor, preferably phosphorus, oxygen, sulphur or lithium, or an acceptor, preferably boron, is used as the dopant and/or
in that the impurity atom is selected from the group consisting of nitrogen, magnesium, carbon, lead, boron, noble gases, silicon, transition metals and tin.

A feature 3 of the disclosure is a method (10) according to any one of features 1 or 2, characterized,
in that the color center is a NV⁻-center (54) and/or
in that the ion bombardment (22) with impurity atoms having an ionic fluence in the range 10⁴ cm⁻² to 10¹⁰ cm⁻², preferably in the range 10⁷ cm⁻² to 10¹⁰ cm⁻², most preferably in the range 10⁸ cm⁻² to 10¹⁰ cm⁻², in particular in the range 10⁹ cm⁻² to 10¹⁰ cm⁻².

A feature 4 of the disclosure is a method (10) according to any one of the features 1 through 3, characterized,
in that the dopant concentration is in the range 10¹⁷ cm⁻³ to 10¹⁹ cm⁻³, preferably between 1×10¹⁸ cm⁻³ and 9×10¹⁸ cm⁻³, and/or
in that the dopant implantation (12) is carried out by bombardment with the dopants, in particular with energies of less than or equal to 150 keV and/or a dopant fluence in the range from 10⁹ cm⁻² to 10¹³ cm⁻², preferably in the range from 10¹⁰ cm⁻² to 10^{12 cm}⁻², in particular in the range from 10¹¹ cm⁻² to 10¹² cm⁻², and/or
in that the dopant implantation (12) takes place in at least two successively different steps, the dopant implantation (12) preferably taking place by dopant bombardment at different fluences and/or energies.

A feature 5 of the disclosure is a method (10) according to any one of the features 1 through 4, characterized,
in that the depth of the implanted dopants is at least equal to the depth of the incorporated impurity atoms and/or
in that the depth of the color centers (54) in the diamond layer (15) is in the range from 5 nm to 100 nm, preferably in the range from 10 rim to 50 nm, particularly preferably in the range from 10 nm to 30 nm, and in particular is between 20 nm and 30 nm.

A feature 6 of the disclosure is a method (10) according to any one of the features 1 through 5, characterized, in that after donor implantation (12) a first tempering step (20) is performed, wherein:
i) the tempering temperature of the first tempering step (20) is preferably in the range 800° C. to 2000° C., in particular in the range 800° C. to 1400° C. and preferably in the range 1000° C. to 1200° C. and/or
ii) the time for the first tempering step (20) is preferably between 1 h and 24 h, in particular between 2 h and 10 h, preferably between 3 h and 6 h.

A feature 7 of the disclosure is a method (10) according to any one of the features 1 through 6, characterized in that a second tempering step (24) is performed after the impurity incorporation (22), wherein:
iii) the tempering temperature of the second tempering step (24) is preferably lower than that of the first tempering step (20) and/or preferably in the range 600° C. to 1300° C., in particular in the range 800° C. to 1000° C. and/or
iv) wherein the time for the second tempering step (24) is preferably between 1 h and 24 h, in particular between 2 h and 10 h, preferably between 3 h and 6 h.

A feature 8 of the disclosure is a method (10) according to any one of the features 1 through 7, characterized in that an increase of the Fermi level is performed, the increase preferably being performed during the impurity implantation (22), after the impurity implantation (22) and/or during the second annealing step (24), the increase being performed in particular by LASER irradiation, electron bombardment or voltage application.

A feature 9 of the disclosure is a method (10) according to any one of the features 1 through 8, characterized
in that the diamond layer (15) is present in a diamond material (14) having at least pure quality, the hydrogen content in the diamond layer (15) preferably being less than 10¹⁷ cm⁻³, and/or
in that the diamond layer (15) is formed as a layer, preferably as a surface layer, within a diamond material (14) extending over a greater depth.

A feature 10 of the disclosure is a diamond layer (15) having at least one deterministic color center (54), characterized in that the impurity species used to form the color center (54) is present in an atomic number in the diamond layer (15) which is at most twice the number of the color center (54) in the diamond layer (15).

A feature 11 of the disclosure is a use of a diamond layer (15) having at least one deterministic color center (54) according to claim 10 or fabricated according to any one of the features 1 through 9 as a qubit container, preferably in the context of a sensor and/or in the context of quantum cryptography and/or in the context of a quantum computing application.

Unless otherwise indicated, all features of the present disclosure may be freely combined with each other. Also, unless otherwise indicated, the features described in the figure description may be freely combined with the other features as features of the disclosure. In this regard, a restriction of individual features of the examples to combination with other features of the examples is expressly not envisaged. In addition, representational features of the diamond coating can also be used as process features in a reformulated form, and process features can be used as representational features of the diamond coating in a reformulated form. Such a reformulation is thus automatically disclosed.

### LIST OF REFERENCE SYMBOLS

10 example process for the production of a deterministic color center
12 first step, implantation of dopants
14 diamond
15 diamond layer
16 ion beam source
18 aperture
20 first tempering step
22 second step, ion bombardment
24 second tempering step
30 trial sample
32, 34, 36 doping regions
38 graphite marker
40, 42, 44, 46 impurity atom regions
50 certain region of the diamond layer without color centers
52 geometrically identically sized region as the certain region 50
54 color centers, NV centers
56 arbitrary region
a, b, c impurity atom regions 40, 42, 44, 46 with different ion fluxes
D_{FZ} density of color centers 54 using the following relationship from the
I_{backg} background intensity
Iₑₙₛ total intensity
I_{ref} intensity of color centers 54
I_{single} reference value
S area of the region 56
T2, T2* spin coherence times
UR conversion rate

1-11. (canceled)

12. A method for generating at least one deterministic NV center in a diamond layer, comprising:
implanting at least one dopant in the diamond layer, wherein the dopant used is one of lithium, oxygen or sulphur; and
incorporating at least one nitrogen atom in the diamond layer by ion bombardment with impurity atoms to form the NV center, wherein the ion bombardment with the impurity atoms has an ionic fluence of up to 10¹⁰ cm⁻².

13. The method according to claim 12, wherein:
the ion bombardment with the impurity atoms takes place with an ionic fluence in a range from 10⁴ cm⁻² to 10¹⁰ cm⁻², and/or
the ion bombardment with the impurity atoms is low-energy with an energy of less than or equal to 100 keV.

14. The method according to claim 13, wherein the ion bombardment with the impurity atoms takes place with an ionic fluence in a range from 10⁹ cm⁻² to 10¹⁰ cm⁻².

15. The method according to claim 12, wherein a dopant concentration is in a range 10¹⁷ cm⁻³ to 10¹⁹ cm⁻³.

16. The method according to claim 12, wherein the dopant implantation is carried out by bombarding the dopants with energies of less than or equal to 150 keV.

17. The method according to claim 12, wherein the dopant implantation is carried out by bombarding the dopants with a dopant fluence in a range of 10⁹ cm⁻² to 10¹³ cm⁻².

18. The method according to claim 12, wherein the dopant implantation is performed in at least two successively different steps, and further wherein the dopant implantation with each of the two successively different steps is performed by dopant bombardment at a different fluence and/or energy other steps of the at least two successively different steps.

19. The method according to claim 12, wherein a depth of the implanted dopants is at least equal to a depth of the incorporated impurity atoms.

20. The method according to claim 12, wherein a depth of the NV centers in the diamond layer is in a range of 5 nm to 100 nm.

21. The method according to claim 12, wherein, after the donor implantation, a first tempering step takes place, wherein:
i) a tempering temperature of a first tempering step is preferably in a range 800° C. to 2000° C.;
and/or
ii) a time for the first tempering step is preferably between 1 h and 24 h.

22. The method according to claim 21, wherein a second tempering step is performed after the impurity incorporation, wherein:
iii) a tempering temperature of a second tempering step is preferably lower than that of the first tempering step and/or in the range 600° C. to 1300° C.;
and/or
iv) wherein the time for the second tempering step is preferably between 1 h and 24 h.

23. The method according to claim 22, wherein a Fermi level is raised, the raising taking place during the impurity implantation, after the impurity implantation and/or during the second tempering step, the raising taking place by LASER irradiation, electron bombardment or voltage application.

24. The method according to claim 12, wherein the diamond layer is present in a diamond material which is at least of pure quality, a hydrogen content in the diamond layer being less than 10¹⁷ cm⁻³.

25. The method according to claim 12, wherein the diamond layer is formed as a surface layer, within a diamond material extending over a greater depth.

26. A diamond layer having at least one deterministic NV⁻ center and dopants, wherein an impurity species used to form the NV⁻ center is present in an atomic number in the diamond layer which is at most twice a number of the NV⁻ centers in the diamond layer, and further wherein the impurity species is nitrogen and wherein lithium, oxygen or sulfur are dopants, a dopant concentration being in a range 10¹⁷ cm⁻³ to 10¹⁹ cm⁻³.

27. Use of a diamond layer comprising at least one deterministic color center according to claim 26 in the context of a sensor and/or in a context of quantum cryptography and/or in the context of a quantum computing application.

28. A quantum computer comprising the diamond layer according to claim 26.

29. A sensor comprising the diamond layer according to claim 26.

30. A device for quantum cryptography, comprising a diamond layer according to claim 26.

31. Use of a diamond layer manufactured according to claim 12 as a qubit container, in the context of a sensor and/or in a context of quantum cryptographs and/or in the context of a quantum computing application.
